(19) United States
(12) Patent Application Publication
(10) Pub. No.: US 2024/0057255 A1
(43) Pub. Date: Feb. 15, 2024

(54) METHOD OF MANUFACTURING A PRINTED CIRCUIT BOARD ASSEMBLY

(71) Applicant: Rolls-Royce Deutschland Ltd & Co KG, Blankenfelde-Mahlow (DE)

(72) Inventors: Stanley BUCHERT, Herzogenaurach (DE); Uwe WALTRICH, Forchheim (DE)

(21) Appl. No.: 18/229,816

(22) Filed: Aug. 3, 2023

(30) Foreign Application Priority Data
Aug. 11, 2022 (DE) 10 2022 120 293.3

(51) Int. Cl. H05K 1/14; H05K 3/12; H05K 3/02; H05K 1/18

(52) U.S. Cl. CPC H05K 1/144; H05K 3/1283; H05K 3/022; H05K 1/181; H05K 2201/0212; H05K 2203/125

(57) ABSTRACT

A method for producing a circuit board arrangement includes: providing a first board in which electrical components and electrical contacts assigned thereto are integrated and include upper first contact surfaces and lower second contact surfaces; providing a second board in which ceramic substrates are integrated and include upper third contact surfaces; providing a multi-layered circuit board that forms lower fourth contact surfaces; simultaneously connecting the upper side of the first board to the lower side of the circuit board and the upper side of the second board to the lower side of the first board, wherein the upper first contact surfaces of the first board are connected to the lower fourth contact surfaces of the circuit board by a first sintering layer, and the lower second contact surfaces of the first board are connected to the upper third contact surfaces of the second board by a second sintering layer.

The present patent document claims the benefit of German Patent Application No. 10 2022 120 293.3, filed Aug. 11, 2022, which is hereby incorporated by reference in its entirety.

### TECHNICAL FIELD

The disclosure relates to a method for producing a circuit board arrangement and a circuit board arrangement produced using the method.

### BACKGROUND

Circuit board-based power electronics assemblies are known, in which power semiconductors embedded in electrical modules are arranged via surface mounting on the lower side of a multi-layered circuit board or carrier board and electrically contacted. The electrical modules, which are each provided with a power semiconductor, are also referred to as prepackage modules. For cooling the prepackage modules, the prepackage modules protrude into cavities of a metallic heat sink and are pressed against the heat sink via a thermal interface material.

The prepackage modules may be produced in circuit boards (main panels) in the panel, then isolated, and subsequently connected to the carrier board. High requirements for air and creepage distances are to be maintained from the aspect of the insulation resistance here with respect to the arrangement of the prepackage modules. This is against the background that the power semiconductors are subjected to a high voltage potential, for example, in the range of 1000 V, via the carrier board. An insulation resistance, in particular in relation to the metallic heat sink, is to be implemented here.

To provide corresponding insulation resistance, arranging potting compounds between the main circuit board and electrical module to produce a solid insulation is known. Such a procedure is linked to disadvantages, however. Thus, there is an increased monitoring effort linked to the manufacturing and an increased discard rate. The risk of flaws in the solid insulation and thus the risk of insulation flaws also cannot be precluded.

### SUMMARY AND DESCRIPTION

The disclosure is based on the object of providing a method for effectively producing a circuit board arrangement, which includes electrical modules, wherein the produced circuit board arrangement is to meet high requirements for air and creepage distances.

This object is achieved by the methods and circuit board arrangements, as described herein. The scope of the present disclosure is defined solely by the appended claims and is not affected to any degree by the statements within this summary. The present embodiments may obviate one or more of the drawbacks or limitations in the related art.

The disclosure accordingly considers a method for producing a circuit board arrangement, wherein the circuit board arrangement includes a circuit board and a plurality of electrical modules connected to the circuit board, wherein each electrical module includes a ceramic substrate and an electrical component arranged on the ceramic substrate. The method includes providing a first board having an upper side and a lower side, in which the electrical components and electrical contacts assigned thereto are integrated, wherein the assigned electrical contacts include upper first contact surfaces on the upper side of the first board and lower second contact surfaces on the lower side of the first board. The method further includes providing a second board having an upper side and a lower side, in which the ceramic substrates are integrated, wherein the ceramic substrates include upper third contact surfaces on the upper side of the second board. The method further includes providing a multi-layered circuit board, wherein the circuit board includes a lower side which forms lower fourth contact surfaces. The method further includes simultaneously connecting the upper side of the first board to the lower side of the circuit board and the upper side of the second board to the lower side of the first board while simultaneously producing the plurality of electrical modules and their arrangement on the lower side of the circuit board. In this case, in the simultaneous connection, the upper first contact surfaces of the first board are connected to the lower fourth contact surfaces of the lower side of the circuit board by sintering by a sintering layer. Additionally, in the simultaneous connection, the lower second contact surfaces of the first board are connected to the upper third contact surfaces of the second board by sintering by a sintering layer.

The disclosure is based on the concept of refraining from isolating the electrical modules produced in the panel and the individual connection thereof to the circuit board and instead arranging a plurality of electrical modules simultaneously in one method act on the lower side of the circuit board. A method is used for this purpose in which the components of the modules are initially integrated in two boards in an upstream act. In a sintering process, on the one hand, the two boards are connected to one another, and, on the other hand, one of the two boards is connected to the circuit board simultaneously. The process of producing the electrical modules in the panel is thus combined with connecting the modules to an outer layer of the circuit board.

The electrical modules produced in the panel and simultaneously connected to the circuit board are positioned and spaced apart from one another here such that they already have the desired configuration on the circuit board. This is necessary, because the electrical modules may no longer be isolated and then placed separately on the circuit board, but rather are connected to the circuit board in the configuration which results from the production in the panel. Accordingly, the electrical components and the electrical contact surfaces of the first board, the ceramic substrates and electrical contact surfaces of the second board, and the contact surfaces of the lower side of the circuit board are arranged in a corresponding predefined grid.

The above-described insulation and field strength problems may be remedied by the combination of the production of the electrical modules with the connection of the electrical modules to the circuit board. The fact that the connection of the electrical modules to the circuit board manages without a soldering process using fluxes contributes thereto. A subsequently applied insulation layer within the gap by underfill is thus not necessary due to the process flow. In a soldering process, the quality of the insulation layer is decisive for the insulation resistance and is strongly dependent on the soldering process and the flux residues. On the contrary, the connection takes place in each case via a sintering layer, wherein all electrical modules are connected simultaneously to the circuit board. The gap between the first board and the circuit board, which is determined by the height of the sintering layer, may be filled by epoxy or circuit board material (FR4). Subsequently introduced insulation material is no longer necessary. A defined thickness of the sintering layer between the electrical modules and the circuit board may be provided here for all electrical modules. In this way, the problem of tilting of the electrical modules during connection to the circuit board and field strength inhomogeneities linked thereto may be reduced. Experiments have shown that with sintering according to the method, a tilt of the individual electrical modules is only still approximately 5 μm, while with soldering the tilt may be significantly higher. The solution moreover simplifies and improves the thermal connection to a heat sink, because smaller gap dimensions have to be compensated for by a thermal interface material.

In the terminology used herein, the side of the circuit board on which the electric modules are arranged is designated as the lower side, independently of the actual spatial orientation of the circuit board and the electrical modules.

The circuit board may also be referred to as a carrier board or main board. The electrical modules are also referred to as prepackage modules.

One embodiment provides that before the connection of the first board to the circuit board, a first precut layer made of a nonconductive material is arranged between the upper side of the first board and the lower side of the circuit board, wherein the first precut layer is cut out in the areas in which the upper first contact surfaces of the first board are formed.

The first precut layer therefore represents a type of template, which lies around the contact surfaces. The first precut layer is formed here such that the first precut layer melts upon the sintering and fills all cavities between the upper side of the first board and the lower side of the circuit board. The first precut layer hardens after the sintering.

In a corresponding manner, before the connection of the second board to the first board, a second precut layer made of a nonconductive material is arranged between the upper side of the second board and the lower side of the first board, wherein the second precut layer is cut out in the areas in which the lower second contact surfaces of the first board are formed. In this case as well, the second precut layer is formed such that the second precut layer melts in the sintering act, fills all cavities between the second board and the first board, and hardens after the sintering act.

The first precut layer and/or the second precut layer may include an epoxy resin that melts upon sintering and then hardens. This may be a fiber-reinforced epoxy resin here. In particular, the first and/or second precut layer may include an insulating circuit board material such as FP4. The first and second precut layers are therefore provided in embodiments by corresponding precut prepreg layers.

The first board and the second board include circuit board material. The first and second precut layers individually include a material that has a lower melting point than the circuit board material of the two boards, so that only the precut layers melt upon sintering, but not the first and second board.

A further embodiment provides that the contact surfaces of the first board, the second board, and the circuit board are formed as metallization surfaces. These are copper surfaces, for example.

A further embodiment provides that the sintering act includes silver sintering using a silver paste. The sintering act takes place here at a temperature in the range of 200° C. to 270° C. or in the range of 230° C. to 250° C. A compression pressure in the range of 5 to 30 MPa or in the range of 8 to 12 MPa may be present during the sintering. Sintering in the mentioned temperature and pressure range provides that the electrical components of the electrical modules are not damaged during the sintering.

One embodiment provides that the electrical contacts integrated in the first board include vias, which extend from the upper first contact surfaces to the lower second contact surfaces or to a metallized upper side of the electrical components. The vias are used here for electrically contacting the electrical components of the respective electrical modules.

The electrical component of the respective electrical modules may be a power semiconductor such as a power MOSFET or an IGBT component. The ceramic circuit carrier of the respective electrical modules is used for electrical insulation of the electrical component from a heat sink and at the same time for thermal connection to the heat sink.

In a further aspect, the present disclosure relates to a circuit board arrangement that is characterized in that the circuit board arrangement is produced by the methods described herein.

In a further aspect, the present disclosure relates to a circuit board arrangement that includes a circuit board and a plurality of electrical modules connected to the circuit board, wherein each electrical module includes a ceramic substrate and an electrical component arranged on the ceramic substrate. The electrical modules are formed without isolation in a board and the board as a whole is connected to the circuit board, wherein contact surfaces of the electrical modules and the circuit board assigned to one another are each connected to one another via a sintering layer.

The board in which the electrical modules are formed is in this case, for example, the first board and second board, which are connected to one another, by the methods disclosed herein.

The circuit board arrangement thus integrates a board produced in the panel with a plurality of electrical modules in a circuit board in that the surface contacts of the electrical modules of the board are connected by sintering to corresponding contact surfaces on the lower side of the circuit board.

### BRIEF DESCRIPTION OF THE DRAWINGS

The disclosure is explained in more detail below on the basis of multiple exemplary embodiments with reference to the figures of the drawing, In the figures:

FIG. 1 depicts an example of components of a circuit board arrangement before their connection by a method in which a plurality of electrical modules is produced and contacted simultaneously on the lower side of a circuit board;

FIG. 2 depicts an example of a circuit board arrangement having the components shown in FIG. 1 after their connection;

FIG. 3 depicts an example a circuit board arrangement (not relating to the disclosure) having a circuit board, a previously isolated electrical module, and a heat sink; and

FIG. 4 depicts an example of a flow chart of a method for producing a circuit board arrangement according to FIGS. 1 and 2.

### DETAILED DESCRIPTION

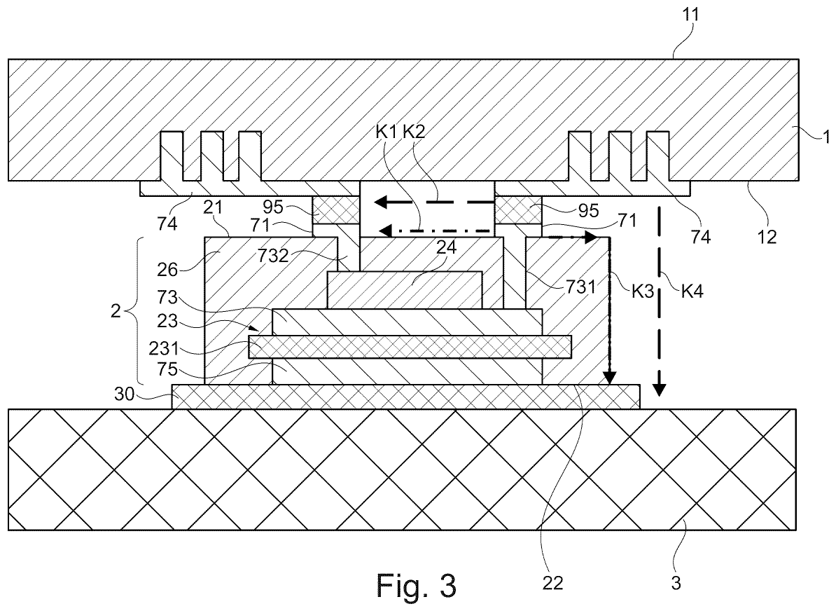

For better understanding of the present disclosure, FIG. 3 depicts a circuit board arrangement in which a single electrical module is arranged on the lower side of a circuit board. The electrical module was produced here in the panel, subsequently isolated, and then connected to the circuit board.

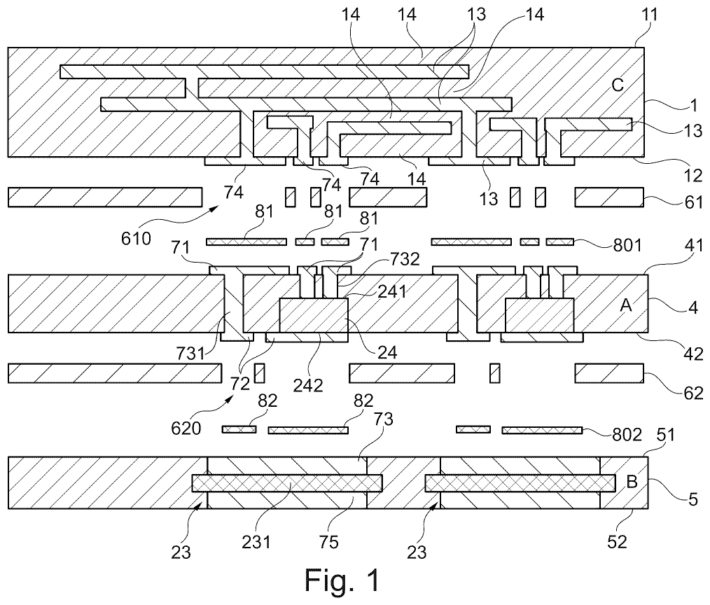

The circuit board arrangement 1 of FIG. 1 includes a circuit board 1, an electrical module 2, and a heat sink 3. The circuit board 1 is multi-layered and forms, for example, a carrier board, on which a plurality of electrical modules 2 and further components are arranged. The circuit board 1 forms an upper side 11 and a lower side 12. A plurality of electrical contact surfaces 74 is formed on the lower side 12, to each of which a defined potential, for example a high voltage potential, is applied. The contact surfaces 74 are, for example, copper surfaces.

The electrical module 2, also referred to as a prepackage module, includes a ceramic circuit carrier 23 and an electrical component 24.

The ceramic circuit carrier 23 includes an insulating ceramic layer 231, an upper metallization layer 73 arranged on the upper side of the ceramic layer 231, and an optional lower metallization layer 75 arranged on the lower side of the ceramic layer 231. The electrical component 24 is arranged on the upper metallization layer 73. The ceramic circuit carrier 23 and the electrical component 24 are arranged in a substrate 26, which defines the external dimensions of the electrical module 2. The substrate 26 may be a circuit board in which the ceramic circuit carrier and the electrical module are embedded.

The ceramic circuit carrier 3 may be a DBC substrate (DBC=“direct bonded copper”). DBC is a connection technology which connects metallization layers to a ceramic layer, such as aluminum oxide. The metallization layers 73, 75 include copper, aluminum, silver, or tungsten, for example.

The upper side 21 of the electrical module 2 includes a plurality of electrical contact surfaces 71, which are formed, for example, by copper surfaces. The upper side 21 of the electrical module 2 is soldered via surface mounting on the circuit board 2, wherein the contact surfaces 71 of the electrical module 2 are electrically connected to the corresponding contact surfaces 74 of the circuit board 1 via solder pads 95.

Furthermore, the electrical contacts include vias 731, which extend from some of the electrical contact surfaces 71 to the upper metallization layer 73 of the ceramic circuit carrier 23, and vias 732, which extend from other ones of the electrical contact surfaces 71 to a metallized surface of the electrical component 24. A lower side potential and upper side potential of the electrical component 24 are provided via these vias 731, 732. For example, the vias 731, 732 provide a source terminal, a gate terminal, and a drain terminal of the electrical component 24.

The lower side of the electrical module 2, which is formed by the lower metallization layer 75, is thermally coupled to the heat sink 3 via a thermal interface material 30, (e.g., a heat conduction mat). The ceramic circuit carrier 23 having the ceramic layer 231 is used for electrical insulation of the electrical component 24 arranged on the ceramic circuit carrier 23 from the heat sink 3, and, at the same time, provides a thermal connection to the heat sink 3.

The electrical component 24 may be a power semiconductor and may be designed as an integrated circuit (chip).

In such a structure, high requirements are to be implemented for air and creepage distances. This is related to a high voltage potential, for example, in the range of 1000 V, e.g., being applied to the contact surfaces 74, 71, 73. A strong electrical field thus exists between the contact surfaces 74 and the heat sink 3, which may be at ground. Corresponding potential creepage distances K1, K3 and air distances K2, K4 are shown in FIG. 3.

FIG. 1 shows the components of a circuit board arrangement that are not yet connected to one another.

The components of the arrangement include a circuit board 1, which corresponds in the fundamental design to the circuit board 1 of FIG. 3. It is provided here that the circuit board 1 is multi-layered and includes a plurality of circuit board layers 13, 14, which are arranged one over another. The individual circuit board layers are formed by electrically insulating layers 14 made of insulating material (for example, FR4 or prepreg layers) and metal layers, (e.g., copper layers), which are connected to one another and structured in a way known per se by laminating and etching processes. An uppermost circuit board layer forms an upper outer layer and at the same time an upper side 11 of the circuit board 1. A lowermost circuit board layer forms a lower outer layer and, at the same time, a lower side 12 of the circuit board 1. The circuit board 1 includes a plurality of electrical contact surfaces 74 on the lower side 12.

The components of the arrangement furthermore include a first board 4, which includes an upper side 41 and a lower side 42. The board 4 may include a nonconductive circuit board material and may be constructed from one or more layers. A plurality of electrical components 24, which correspond to the electrical components 24 of FIG. 3, are integrated in the first board 4. Furthermore, the required electrical contacts for contacting the respective electrical component 24 are integrated in the board 4. These electrical contacts include contact surfaces 71 on the upper side 41 of the board 4 and contact surfaces 72 on the lower side of the board 4. The electrical contacts furthermore include vias 731, which extend from some of the contact surfaces 71 on the upper side 41 of the board 4 to some of the contact surfaces 72 on the lower side 42 of the board 4. Furthermore, the electrical contacts include vias 732, which extend from other ones of the contact surfaces 71 on the upper side 41 of the board to the upper side 241 of the electrical components 24, wherein the upper side 41 may be metallized.

In the finished mounted state, the lower side potential, (e.g., a drain terminal of the electrical components 24), is provided via the vias 731, wherein the lower contact surfaces 72 are electrically connected to one another and the lower side potential provided via the vias 731 is applied to the lower side 242 of the electrical components 24. Upper side potentials, (e.g., a source terminal and a gate terminal), are provided on the upper side 241 of the electrical components 24 via the further vias 732.

The individual electrical components 24 and assigned electrical contacts are integrated in a defined pattern, for example, in one or more rows or in a defined grid in the first board 4. They are arranged here such that the upper contact surfaces 71 are aligned opposite to the lower contact surfaces 74 on the lower side 12 of the circuit board 11.

The components of the arrangement furthermore include a second board 5, which includes an upper side 51 and a lower side 52. The board 5 may include a nonconductive circuit board material and may be constructed from one or more layers. A plurality of ceramic substrates 23 are integrated in the board 5, which correspond with respect to their design to the ceramic substrates 23 of FIG. 3. The ceramic substrates 23 thus each include a ceramic layer 231, an upper metallization layer 73, and a lower metallization layer 75.

A first precut layer 61 is arranged between the first board 4 and the circuit board 1. The layer 61 may also include a nonconductive circuit board material, wherein the circuit board material used for the layer 61 has a lower melting temperature than the circuit board material used for the nonconductive layers of the circuit board 1 and for the boards 4, 5. The layer 61 is precut insofar as it has openings 610 in the areas which adjoin the electrical contacts 71 on the upper side 41 of the board 4.

In a corresponding manner, a second precut layer 62 made of a nonconductive circuit board material is arranged between the second board 5 and the first board 4. In this case as well, the circuit board material used for the layer 62 has a lower melting temperature than the circuit board material used for the nonconductive layers of the circuit board 1 and for the boards 4, 5. The layer 62 is precut insofar as it has openings 620 in the areas which adjoin the electrical contacts 72 on the lower side 42 of the board 4.

The components of the arrangement furthermore include two sintering layers 801, 802, wherein one sintering layer 801 extends between the first board 4 and the circuit board 1 and the other sintering layer 802 extends between the second board 5 and the first board 4. The sintering layers 801, 802 each include sections made of sintering solder 81, 82, which are dimensioned such that they just correspond to the openings 610, 620 in the precut layers 61, 62. The sintering layers 801, 802 are insofar not coherent layers, but rather they include individual sections 81, 82 made of sintering solder. The sintering solder is, for example, a silver solder.

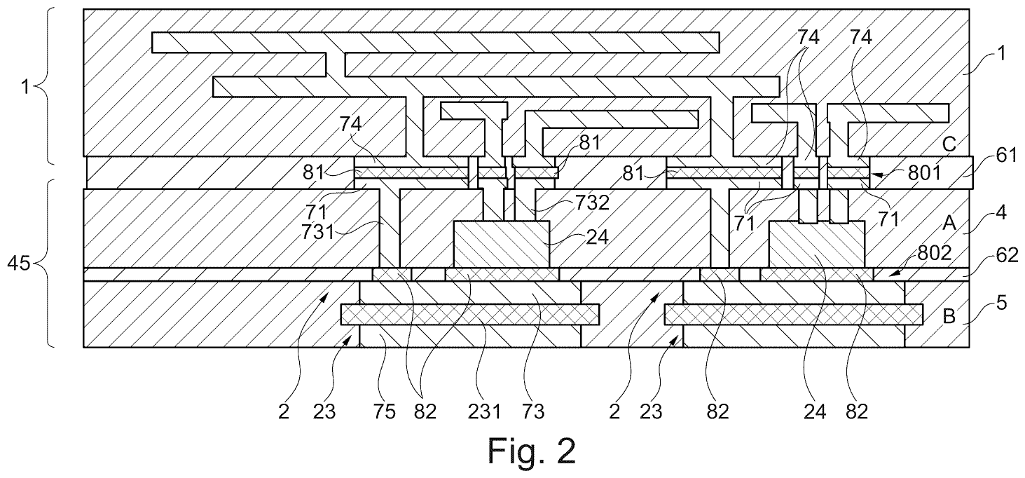

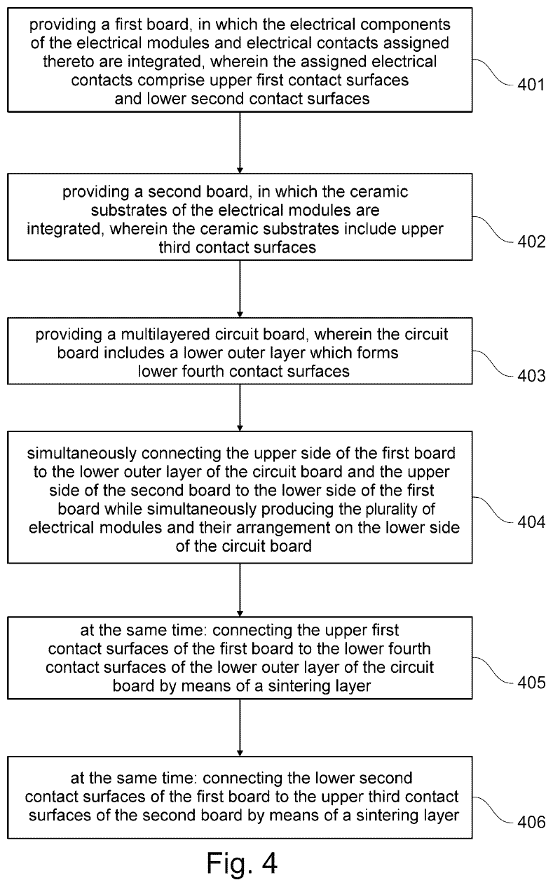

FIG. 2 shows the components of the arrangement of FIG. 1 in the assembled state. FIG. 4 explains the production method for this purpose. According to method acts 401, 402, and 403, a first board 4, a second board 5, and a circuit board 1 corresponding to FIG. 1 are provided. These three components are connected simultaneously by sintering, wherein according to act 404, the upper side 41 of the first board 4 is connected to the lower side 12 of the circuit board 1 and the upper side 51 of the second board 5 is connected to the lower side 42 of the first board 4. During this connection process, a plurality of electrical modules 2 is produced simultaneously, which correspond to the electrical modules 2 of FIG. 3 but remain in the board composite. These electrical modules 2 are simultaneously connected to the circuit board 1 and contacted therewith.

In this case, according to act 405, the upper contact surfaces 41 of the board 4 are connected to the lower contact surfaces 74 on the lower side 12 of the circuit board 1 by sintering by the sintering layer 801. Furthermore, according to act 406, the lower contact surfaces 72 of the board 4 are connected to the upper contact surfaces 73 (which are formed by the upper metallization layers 73) by sintering by the sintering layer 802. The precut layers 61, 62 melt upon the sintering here and fill all cavities, on the one hand, between the upper side 41 of the board 4 and the lower side 12 of the circuit board 1 and, on the other hand, between the board 5 and the board 4. The layers 61, 62 in particular press tightly against the sections 81, 82 made of sintering solder and respective contact surfaces 71-74.

The sections 81, 82 made of sintering solder are arranged here precisely in the openings 610, 620 of the precut layers 61, 62, so that the respective assigned electrical contact surfaces 71, 74 and 72, 73 come into electrical contact via the sections 81, 82 made of sintering solder. On both sides, a mechanical connection between the second board 5, the first board 4, and the circuit board 1 is produced via the sintering layers 801, 802 and the precut layers 61, 62. The second board 5 and the first board 4 together form a board 45 here, in which the finished electrical modules 2 are formed without isolation.

The sintering process is carried out in case of silver sintering in a temperature range of 200° C. to 270° C. or in the range of 230° C. to 250° C. A compression pressure in the range of 5 to 30 MPa may be implemented here. This is however to be understood solely as an example. Other temperatures and pressures may also be implemented depending on the materials used for the sintering.

In an alternative method, the board 45 is first produced by sintering from the two boards 4, 5. This board 45 is then connected by sintering to the lower side 12 of the circuit board 1.

It is understood that the disclosure is not restricted to the embodiments described above, and various modifications and improvements may be made without departing from the concepts described herein. It is furthermore to be noted that any of the features described may be used separately or in combination with any other features, provided that they are not mutually exclusive. The disclosure extends to and includes all combinations and sub-combinations of one or more features which are described here. If ranges are defined, these ranges therefore include all the values within these ranges as well as all the partial ranges that lie within a range.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

1. A method for producing a circuit board arrangement, wherein the circuit board arrangement comprises a circuit board and a plurality of electrical modules connected to the circuit board, wherein each electrical module of the plurality of electrical modules comprises a ceramic substrate and an electrical component arranged on the ceramic substrate, the method comprising:
providing a first board having an upper side and a lower side, in which the electrical components of the plurality of electrical modules and electrical contacts assigned thereto are integrated, wherein the assigned electrical contacts comprise upper first contact surfaces on the upper side of the first board and lower second contact surfaces on the lower side of the first board;
providing a second board having an upper side and a lower side, in which the ceramic substrates of the plurality of electrical modules are integrated, wherein the ceramic substrates comprise upper third contact surfaces on the upper side of the second board;
providing a multi-layered circuit board, wherein the multi-layered circuit board comprises a lower side that provides lower fourth contact surfaces; and
simultaneously connecting the upper side of the first board to the lower side of the multi-layered circuit board and the upper side of the second board to the lower side of the first board while simultaneously producing the plurality of electrical modules and an arrangement of the plurality of electrical modules on the lower side of the multi-layered circuit board,
wherein, during the simultaneously connecting, the upper first contact surfaces of the first board are connected to the lower fourth contact surfaces of the lower side of the multi-layered circuit board by sintering by a first sintering layer, and
wherein, during the simultaneously connecting, the lower second contact surfaces of the first board are connected to the upper third contact surfaces of the second board by sintering by a second sintering layer.

2. The method of claim 1, wherein, before the first board is connected to the multi-layered circuit board, a first precut layer made of a nonconductive material is arranged between the upper side of the first board and the lower side of the multi-layered circuit board, and
wherein the first precut layer is cut out in areas in which the upper first contact surfaces of the first board are formed.

3. The method of claim 2, wherein the first precut layer is formed such that the first precut layer melts during the sintering and fills all cavities between the upper side of the first board and the lower side of the multi-layered circuit board and hardens after the sintering.

4. The method of claim 3, wherein the first precut layer comprises an epoxy resin.

5. The method of claim 3, wherein the first precut layer is formed by a circuit board material.

6. The method of claim 1, wherein, before the second board is connected to the first board, a second precut layer made of a nonconductive material is arranged between the upper side of the second board and the lower side of the first board, and
wherein the second precut layer is cut out in areas in which the lower second contact surfaces of the first board are formed.

7. The method of claim 6, wherein the second precut layer is formed such that the second precut layer melts during the sintering and fills all cavities between the second board and the first board and hardens after the sintering.

8. The method of claim 7, wherein the second precut layer comprises an epoxy resin.

9. The method of claim 7, wherein the second precut layer is formed by a circuit board material.

10. The method of claim 1, wherein the contact surfaces of the first board, the second board, and the multi-layered circuit board are formed as metallization surfaces.

11. The method of claim 10, wherein the metallization surfaces are copper surfaces.

12. The method of claim 1, wherein the sintering comprises silver sintering using a silver paste.

13. The method of claim 12, wherein the sintering is carried out at a temperature in a range of 200° C. to 270° C.

14. The method of claim 12, wherein the sintering is carried out at a temperature in a range of 230° C. to 250° C.

15. The method of claim 1, wherein the sintering takes place at a compression pressure in a range of 8 to 12 MPa.

16. The method of claim 1, wherein the electrical contacts integrated in the first board comprise vias that extend from the upper first contact surfaces to the lower second contact surfaces or to a metallized upper side of the electrical components.

17. A circuit board arrangement comprising:
a plurality of electrical modules, wherein each electrical module of the plurality of electrical modules comprises a ceramic substrate and an electrical component arranged on the ceramic substrate;
a first board having an upper side and a lower side, wherein the electrical components of the plurality of electrical modules and electrical contacts assigned thereto are integrated, wherein the assigned electrical contacts comprise upper first contact surfaces on the upper side of the first board and lower second contact surfaces on the lower side of the first board;
a second board having an upper side and a lower side, wherein the ceramic substrates of the plurality of electrical modules are integrated, wherein the ceramic substrates comprise upper third contact surfaces on the upper side of the second board; and
a multi-layered circuit board comprising a lower side that provides lower fourth contact surfaces,
wherein the upper side of the first board is connected to the lower side of the multi-layered circuit board and the upper side of the second board is connected to the lower side of the first board,
wherein an arrangement of the plurality of electrical modules are connected on the lower side of the multi-layered circuit board,
wherein the upper first contact surfaces of the first board are connected to the lower fourth contact surfaces of the lower side of the multi-layered circuit board a first sintering layer, and
wherein the lower second contact surfaces of the first board are connected to the upper third contact surfaces of the second board by a second sintering layer.

18. A circuit board arrangement comprising:
a circuit board; and
a plurality of electrical modules connected to the circuit board, wherein each electrical module comprises a ceramic substrate and an electrical component arranged on the ceramic substrate,
wherein the plurality of electrical modules is formed without isolation in a board,
wherein the board as a whole is connected to the circuit board, and
wherein contact surfaces, which are assigned to one another, of the plurality of electrical modules and the circuit board are each connected to one another via a sintering layer.
